(19) United States
(12) Patent Application Publication
(10) Pub. No.: US 2019/0259349 A1
(43) Pub. Date: Aug. 22, 2019

(54) DISPLAY PANEL

(71) Applicant: Sharp Kabushiki Kaisha, Sakai City (JP)

(72) Inventors: Yasuyoshi KAISE, Sakai City (JP); Keiichi INA, Sakai City (JP); Yoshimizu MORIYA, Sakai City (JP); Ryohji YAYOTANI, Sakai City (JP); Shige FURUTA, Sakai City (JP); Hidekazu YAMANAKA, Sakai City (JP)

(21) Appl. No.: 16/224,938

(22) Filed: Dec. 19, 2018

(30) Foreign Application Priority Data
Feb. 16, 2018 (JP) 2018-026450

(51) Int. Cl. G09G 3/36; G02F 1/1343; H01L 27/12

(52) U.S. Cl. CPC G09G 3/3688; G02F 1/134309; H01L 27/1225; G09G 2320/0223; G02F 2201/56; G09G 2320/0233; G09G 3/3677

(57) ABSTRACT

Luminance unevenness in a display area having an irregular shape is suppressed. A display panel is a display panel in which a cutout is provided, including: a display area in which sub pixels are provided; a non-display zone which is located between the cutout and the display area; a scanning signal line which is provided so as to pass through the display area and the non-display zone; an electric conductor which is at least partially located in the non-display zone; and an insulating film, the scanning signal line being provided so as to overlap with the electric conductor via the insulating film.

This Nonprovisional application claims priority under 35 U.S.C. § 119 on Patent Application No. 2018-026450 filed in Japan on Feb. 16, 2018, the entire contents of which are hereby incorporated by reference.

### TECHNICAL FIELD

The present invention relates to a display panel.

### BACKGROUND ART

Patent Literature 1 discloses a technique of suppressing luminance unevenness in a display area having an irregular shape (such a shape that corners are obliquely cut off).

### CITATION LIST

### Patent Literature

[Patent Literature 1] Japanese Patent Application Publication, Tokukai, No. 2012-103335 (published on May 31, 2012)

### SUMMARY OF INVENTION

### Technical Problem

According to the technique disclosed in Patent Literature 1, there is a problem that a shape of the display area is limited. In addition, there is a problem that adjustment of a data signal is needed.

### Solution to Problem

A display panel in accordance with an aspect of the present invention is a display panel in which a cutout or a hole is provided, including: a display area in which sub pixels are provided; a non-display zone which is located between the cutout or the hole and the display area; a scanning signal line which is provided so as to pass through the display area and the non-display zone; an electric conductor which is at least partially located in the non-display zone; and an insulating film, the scanning signal line being provided so as to overlap with the electric conductor via the insulating film.

### Advantageous Effects of Invention

According to an aspect of the present invention, it is possible to suppress luminance unevenness of a display panel having a cutout or a hole therein and accordingly having an irregular shape.

### BRIEF DESCRIPTION OF DRAWINGS

(a) of FIG. 1 is a schematic view illustrating a configuration of a display device in accordance with Embodiment 1. (b) of FIG. 1 is a cross-sectional view illustrating the configuration of the display device. (c) of FIG. 1 is a circuit diagram illustrating a sub pixel.

(a) of FIG. 2 is a plan view illustrating a configuration of a vicinity of a cutout in Embodiment 1. (b) of FIG. 2 is a cross-sectional view illustrating the configuration of the vicinity of the cutout, viewed along arrows b-b in (a) of FIG. 2.

(a) of FIG. 3 is a schematic view illustrating a configuration of a gate driver (GD1). (b) of FIG. 3 is a timing chart illustrating operation of the gate driver.

(a) of FIG. 4 is a schematic view illustrating a configuration of another gate driver (GD2). (b) of FIG. 3 is a timing chart illustrating operation of the another gate driver.

FIG. 5 is a waveform chart illustrating an effect of Embodiment 1.

FIG. 6 is a waveform chart illustrating a waveform of Comparative Example.

FIG. 7 is a schematic view illustrating variations of a liquid crystal panel in Embodiment 1.

(a) of FIG. 8 is a plan view illustrating a configuration of a vicinity of a cutout in Embodiment 2. (b) of FIG. 8 is a cross-sectional view illustrating the configuration of the vicinity of the cutout, viewed along arrows b-b in (a) of FIG. 8.

(a) of FIG. 9 is a plan view illustrating a configuration of a vicinity of a cutout in Embodiment 3. (b) of FIG. 9 is a cross-sectional view illustrating the configuration of the vicinity of the cutout, viewed along arrows b-b in (a) of FIG. 9.

(a) of FIG. 10 is a plan view illustrating a configuration of a vicinity of a cutout in Embodiment 4. (b) of FIG. 10 is a cross-sectional view illustrating the configuration of the vicinity of the cutout, viewed along arrows b-b in (a) of FIG. 10.

### DESCRIPTION OF EMBODIMENTS

(a) of FIG. 1 is a schematic view illustrating a configuration of a display device in accordance with Embodiment 1. (b) of FIG. 1 is a cross-sectional view illustrating the configuration of the display device. (c) of FIG. 1 is a circuit diagram illustrating a sub pixel. As illustrated in FIG. 1, a display device 2 includes a backlight unit BU, a liquid crystal panel LP (display panel), a source driver SD, and a display control circuit DCC. A gate driver GD1 and a gate driver GD2 are monolithically provided to the liquid crystal panel LP (GDM structure). The display control circuit DCC controls the source driver SD, the gate driver GD1, and the gate driver GD2.

The liquid crystal panel LP includes (i) an active matrix substrate 3 which includes data signal lines DL, scanning signal lines including a scanning signal line Gm and a scanning signal line Gn, the gate driver GD1, and the gate driver GD2, (ii) a liquid crystal layer 4, (iii) a color filter substrate 5 which includes a color filter, and (iv) a functional layer 6 which includes an optical film and touch panel.

The liquid crystal panel LP is a panel having a cutout NZ and accordingly having an irregular shape. A plurality of sub pixels (SPm, SPn, SPM, SPN) are provided in a display area DA.

A sub pixel SPi (i=m, n, M, N) includes a transistor TR and a pixel electrode PE. The sub pixel SPi is connected to (i) a scanning signal line Gi (i=m, n) and (ii) a data signal line DL. A data signal is supplied to the sub pixel SPi through the data signal line DL. Specifically, the pixel electrode PE is connected to the data signal line DL via the transistor TR, and a gate electrode of the transistor TR is connected to the scanning signal line Gi. A liquid crystal capacitance Clc is formed between the pixel electrode PE and a common electrode corn, and a storage capacitance Ccs is formed between the pixel electrode PE and a storage capacitor wiring CSi. Note that the storage capacitor wiring CSi is provided to the active matrix substrate 3, and the common electrode com is provided to the active matrix substrate 3 or the color filter substrate 5. An oxide semiconductor (for example, an In—Ga—Zn—O-based semiconductor), low-temperature polysilicon (LTPS), amorphous silicon, or the like can be used for a channel of the transistor TR.

### Embodiment 1

In FIG. 1, the gate driver GD1 and the gate driver GD2 are provided in a non-display area NA (in which no sub pixel is provided) which surrounds the display area DA (in which the plurality of sub pixels are provided and in which an image can be displayed). The display area DA includes (i) a side area SA1 that is located by one of sides of the cutout NZ which sides face each other in a direction in which the scanning signal lines extend (a right-and-left direction of (a) of FIG. 1), (ii) a side area SA2 that is located by the other one of the sides of the cutout NZ, and (iii) a main area MA that is located further inside than the cutout NZ as viewed in a direction in which the data signal lines DL extend (in the middle in an up-and-down direction of (a) of FIG. 1). The non-display area NA includes non-display zones HZ, one of which is located between the cutout NZ and the side area SA1 and the other one of which is located between the cutout NZ and the side area SA2. According to the liquid crystal panel LP illustrated in FIG. 1, it is possible to dispose a camera lens, various sensors, and/or the like so that the camera lens, the various sensors, and/or the like are/is located in the cutout NZ.

The scanning signal line Gm is provided so as to pass through the main area MA, and is connected to the gate driver GD1 and the gate driver GD2. The scanning signal line Gn is provided so as to pass through the side area SA1, the side area SA2, and the non-display zones HZ, and is connected to the gate driver GD1 and the gate driver GD2.

The number of sub pixels which are connected to the scanning signal line Gn is less than the number of sub pixels which are connected to the scanning signal line Gm. Therefore, as viewed from each of the gate drivers GD1 and GD2, the scanning signal line Gn is a low-load scanning signal line as compared with the scanning signal line Gm.

(a) of FIG. 2 is a plan view illustrating a configuration of a vicinity of the cutout in Embodiment 1. (b) of FIG. 2 is a cross-sectional view illustrating the configuration of the vicinity of the cutout, viewed along arrows b-b in (a) of FIG. 2. As illustrated in FIG. 2, the active matrix substrate 3 is configured such that the following members are provided on a substrate 10: (i) semiconductor films SC; (ii) an inorganic insulating film 14 which is provided in a layer higher than a layer in which the semiconductor films SC are provided; (iii) gate electrodes GE which are provided in a layer higher than the layer in which the inorganic insulating film 14 is provided; (iv) an inorganic insulating film 16 which is provided in a layer higher than the layer in which the gate electrodes GE are provided; (v) the data signal lines DL which are provided in a layer higher than the layer in which the inorganic insulating film 16 is provided; (vi) an inorganic insulating film 18 which is provided in a layer higher than the layer in which the data signal lines DL are provided; (vii) an organic insulating film 20 which is provided in a layer higher than the layer in which the inorganic insulating film 18 is provided; (viii) pixel electrodes PE which are provided in a layer higher than the layer in which the organic insulating film 20 is provided; (ix) an inorganic insulating film 21 which is provided in a layer higher than the layer in which the pixel electrodes PE are provided; (x) the common electrode com which is provided in a layer higher than the layer in which the inorganic insulating film 21 is provided; (xi) an inorganic insulating film 22 which is provided in a layer higher than the layer in which the common electrode com is provided; and (xii) an alignment film (not illustrated) which is provided in a layer higher than the layer in which the inorganic insulating film 22 is provided.

Silicon nitride or silicon oxide can be, for example, used for the inorganic insulating films 14, 16, 18, 21, and 22. Meanwhile, an applicable photosensitive organic material, such as polyimide or acrylic, can be, for example, used for the organic insulating film (planarizing film) 20. A light transmissive conductive film, such as ITO or IZO, can be used for the pixel electrodes PE and the common electrode com. Aluminum (Al), tungsten (W), molybdenum (Mo), tantalum (Ta), chrome (Cr), titanium (Ti), or copper (Cu) can be, for example, used for the gate electrodes GE and the data signal lines DL.

Transistors TR are each constituted by a corresponding one of the gate electrodes GE and a corresponding one of the semiconductor films SC. A source region (low-resistance region) of each of the semiconductor films SC is connected to a corresponding one of the data signal lines DL via a contact hole, and a drain region (low-resistance region) of each of the semiconductor films SC is connected to a corresponding one of the pixel electrodes PE via a contact hole. Note that orientation in the liquid crystal layer 4 (FIG. 1) is controlled by a transverse electric field generated between the pixel electrodes PE and the common electrode com.

The scanning signal line Gn (provided in the layer in which the gate electrodes GE are provided), to which corresponding ones of the gate electrodes GE are connected, is provided so as to pass through the side area SA1 and the side area SA2, which are part of the display area DA, and the non-display zones HZ. The scanning signal line Gn has wide parts Gh which are parts obtained by making the scanning signal line Gn partially wider and which are located in the respective non-display zones HZ.

In each of the non-display zones HZ, electric conductors Ms are provided in the layer in which the semiconductor films SC of the transistors TR are provided. Each of the wide parts Gh of the scanning signal line Gn is provided so as to overlap with a corresponding one of the electric conductors Ms via the inorganic insulating film 14. Each of the electric conductors Ms are connected to a trunk wire Wp (constant voltage wire) via a corresponding one of contact holes CH and a corresponding one of branch wires Wb. This allows a capacitance to be formed between (i) the each of the wide parts Gh of the scanning signal line Gn and (ii) the corresponding one of the electric conductors Ms.

The electric conductors Ms can be formed by a process identical to that for forming the low-resistance regions (source regions and drain regions) of the semiconductor films SC. A common voltage Vcom is supplied to the common electrode com, and a low-voltage power source voltage Vss and a high-voltage power source voltage Vdd are supplied to each of the gate drivers GD1 and GD2. A constant voltage (for example, Vcom, Vss, or Vdd) can be supplied to the trunk wire Wp.

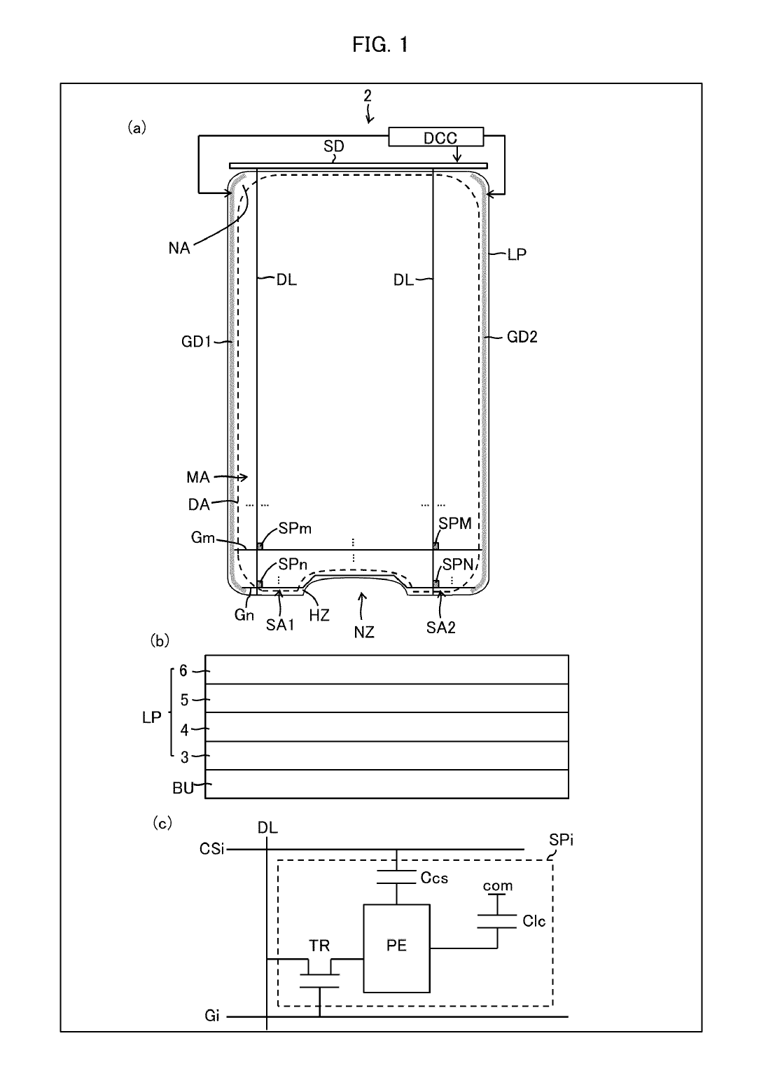

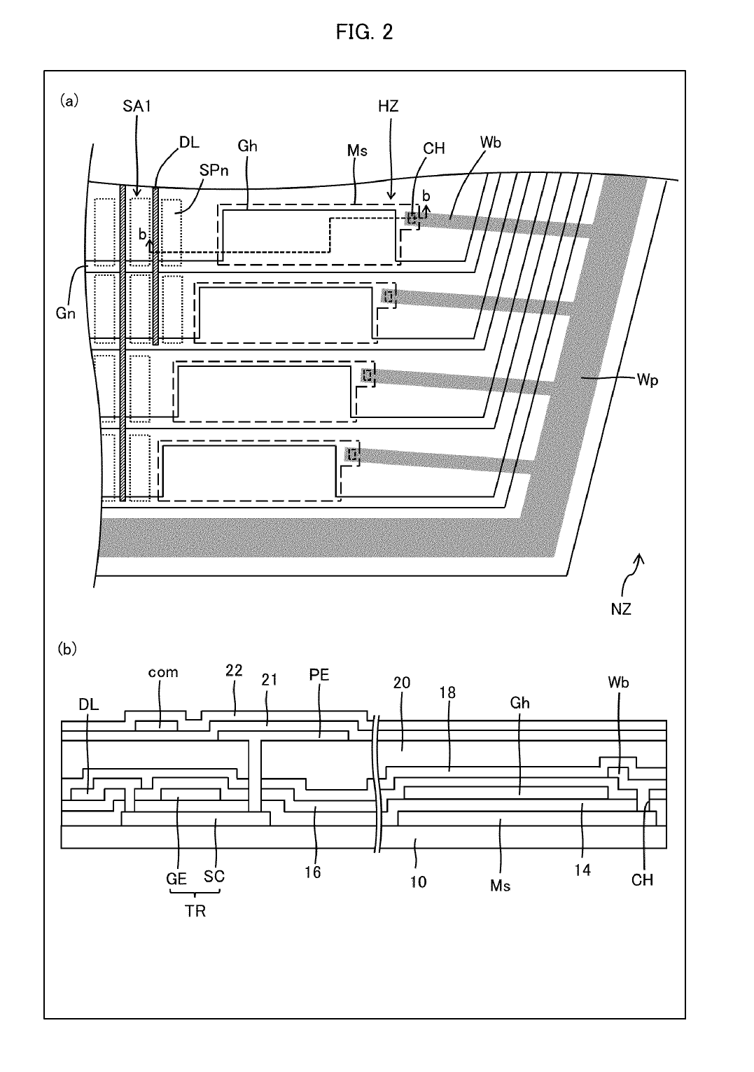

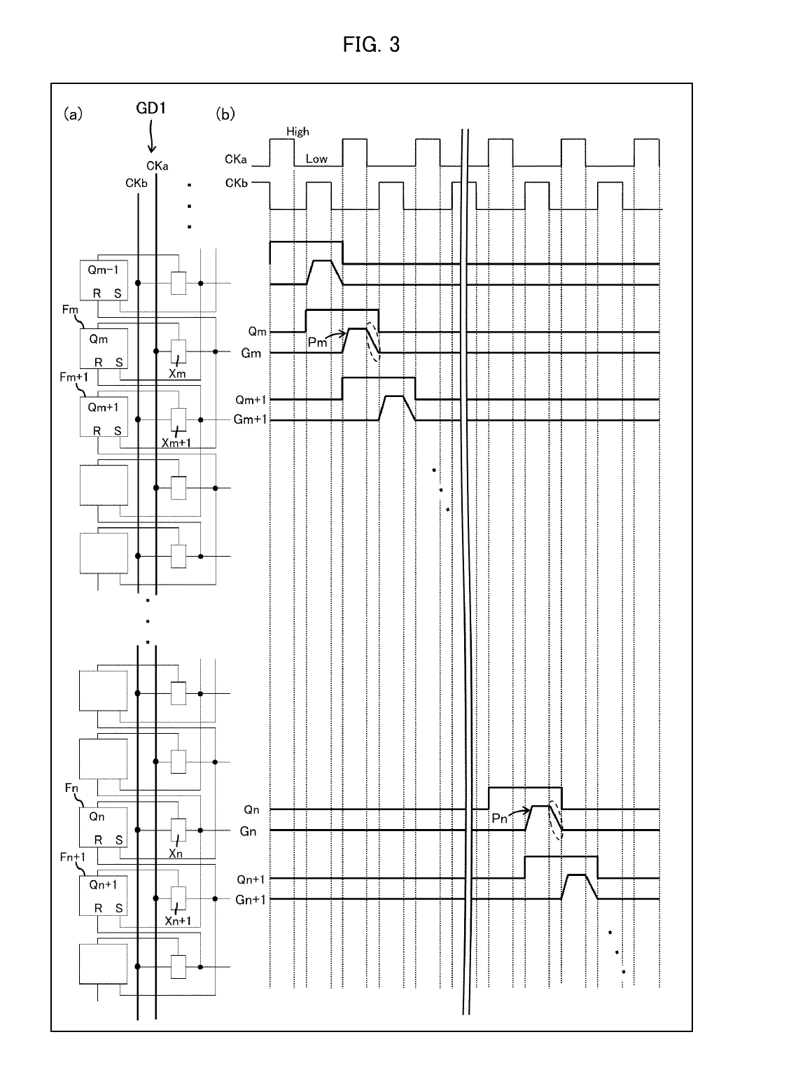

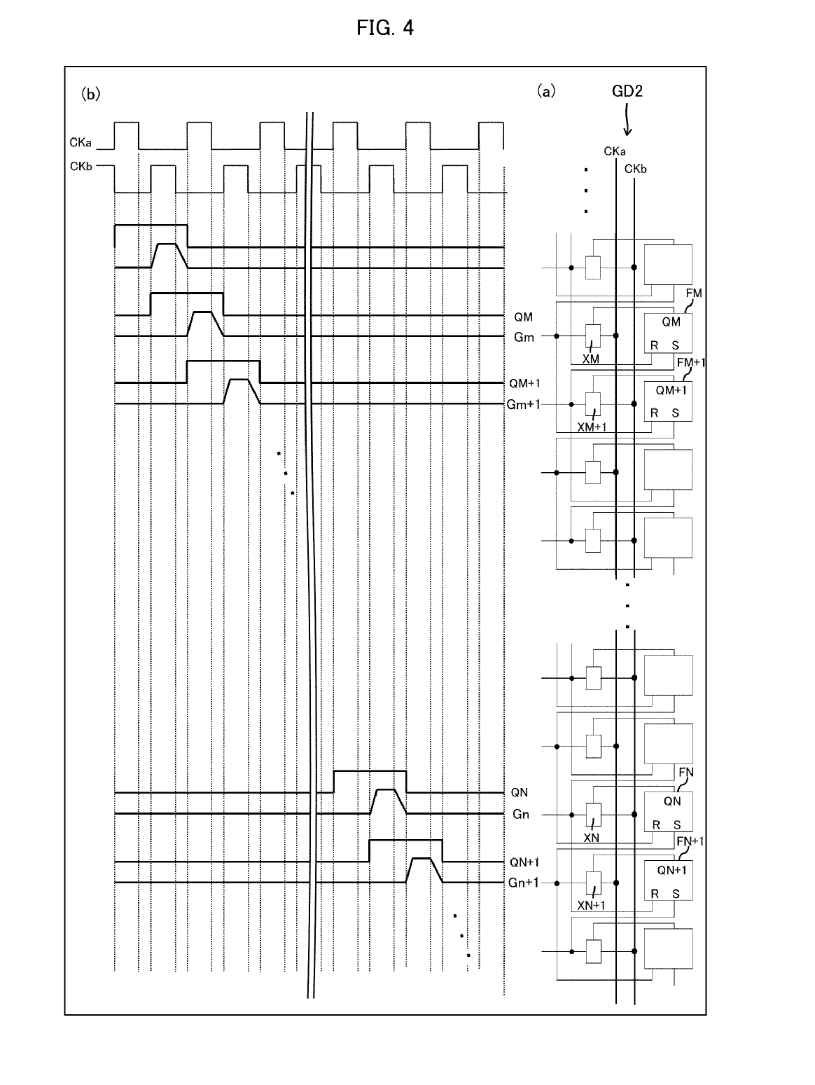

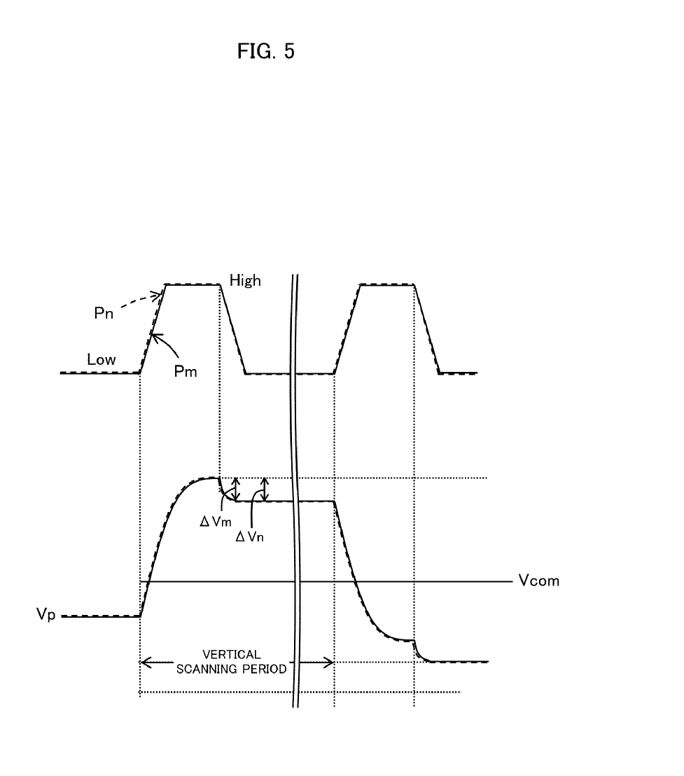

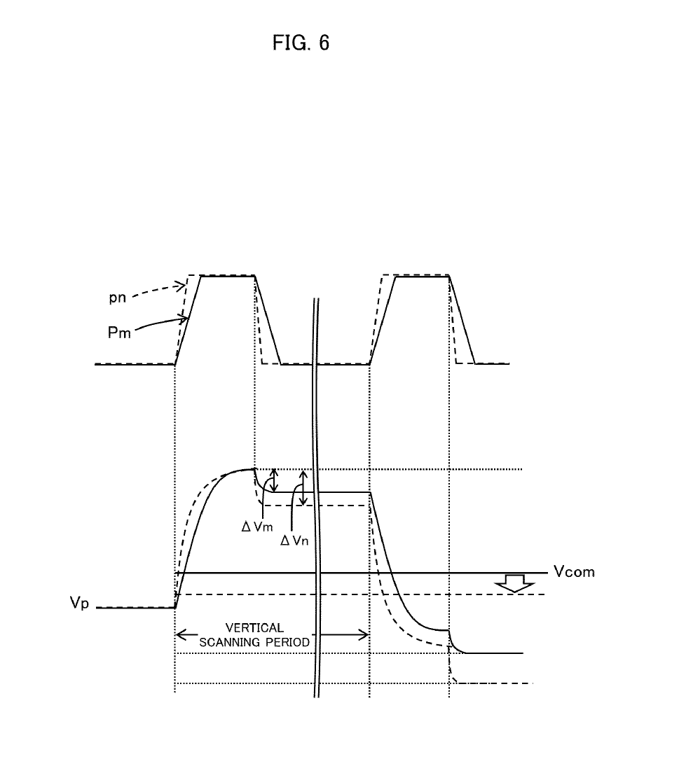

(a) of FIG. 3 is a schematic view illustrating a configuration of the gate driver (GD1). (b) of FIG. 3 is a timing chart illustrating operation of the gate driver (GD1). (a) of FIG. 4 is a schematic view illustrating a configuration of the gate driver (GD2). (b) of FIG. 4 is a timing chart illustrating operation of the gate driver (GD2). FIG. 5 is a waveform chart illustrating an effect of Embodiment 1. FIG. 6 is a waveform chart illustrating a waveform of Comparative Example.

The gate driver GD1 includes a plurality of flip flops and a plurality of output circuits. An output circuit Xm connected to an mth flip flop Fm is connected to the scanning signal line Gm. An output circuit Xn connected to an nth flip flop Fn is connected to the scanning signal line Gn.

The gate driver GD2 includes a plurality of flip flops and a plurality of output circuits. An output circuit XM connected to an mth flip flop FM is connected to the scanning signal line Gm. An output circuit XN connected to an nth flip flop FN is connected to the scanning signal line Gn.

According to Embodiment 1, in each of the non-display zones HZ, a capacitance is added to the scanning signal line Gn, which is a low-load scanning signal line as compared with the scanning signal line Gm. This allows (i) a returning edge (falling edge enclosed by a broken line in FIG. 3) of a scanning pulse Pn which is outputted from the output circuit Xn to the scanning signal line Gn and (ii) a returning edge of a scanning pulse Pn which is outputted from the output circuit XN to the scanning signal line Gn to match (a) a returning edge of a scanning pulse Pm which is outputted from the output circuit Xm to the scanning signal line Gm and (b) a returning edge of a scanning pulse Pm which is outputted from the output circuit XM to the scanning signal line Gm, as illustrated in (b) of FIG. 3, (b) of FIG. 4, and FIG. 5. It is therefore possible to reduce luminance unevenness between the side area SA1, the side area SA2, and the main area MA.

As illustrated in FIG. 5, with regard to the scanning signal line Gm, a voltage Vp of each pixel electrode PE is pulled in a negative direction by AVm at a timing at which the scanning pulse Pm returns (falls), and, with regard to the scanning signal line Gn, a voltage Vp of each pixel electrode PE is pulled in the negative direction by ΔVn at a timing at which the scanning pulse Pn returns (falls). Such a feed-through voltage ΔVm and a feed-through voltage ΔVn each result from a parasitic capacitance between the scanning signal line and the pixel electrode (Cgd). A suitable value of the voltage Vcom of the common electrode is dependent on the feed-through voltage ΔVm and the feed-through voltage ΔVn. The feed-through voltage ΔVm is dependent on the returning edge of the scanning pulse Pm, and the feed-through voltage ΔVn is dependent on the returning edge of the scanning pulse Pn. Therefore, by causing the returning edge of the scanning pulse Pm and the returning edge of the scanning pulse Pn to match each other, the suitable value of the voltage Vcom for the side area SA1, the suitable value of the voltage Vcom for the side area SA2, and the suitable value of the voltage Vcom for the main area MA are caused to match each other. This suppresses luminance unevenness.

Note that, in a case where a capacitance is not added to the scanning signal line Gn, a scanning pulse pn outputted to the scanning signal line Gn returns (drops) more steeply than the scanning pulse Pm outputted to the scanning signal line Gm, so that ΔVn becomes greater than AVm. This causes the suitable value of the voltage Vcom for the side area SA1 and the suitable value of the voltage Vcom for the side area SA2 to shift in the negative direction from the suitable value of the voltage Vcom for the main area MA (see FIG. 6), and may cause luminance unevenness or image sticking (decrease in reliability). Note that a shift of the suitable value of the voltage Vcom can be adjusted by adjusting a data signal to be written in each pixel electrode PE. However, in this case, it is disadvantageously necessary to customize the source driver SD. According to Embodiment 1, by designing the non-display zones HZ of the active matrix substrate 3, there is an advantage that it is possible to deal with luminance unevenness.

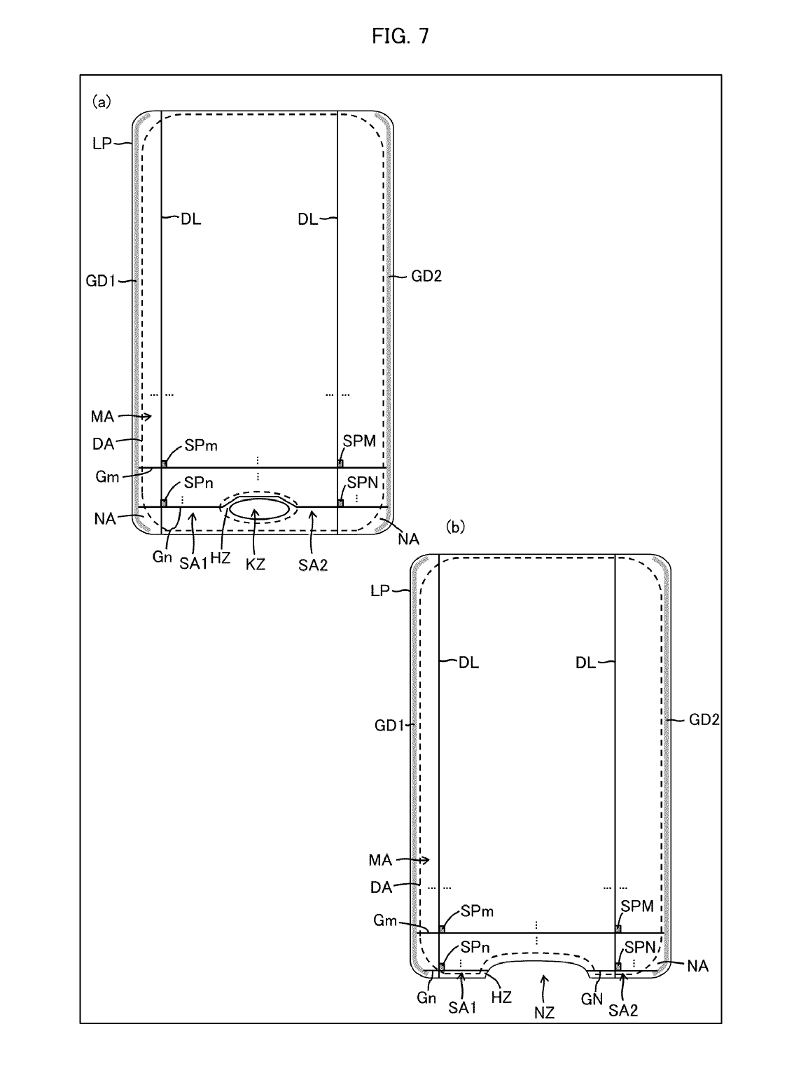

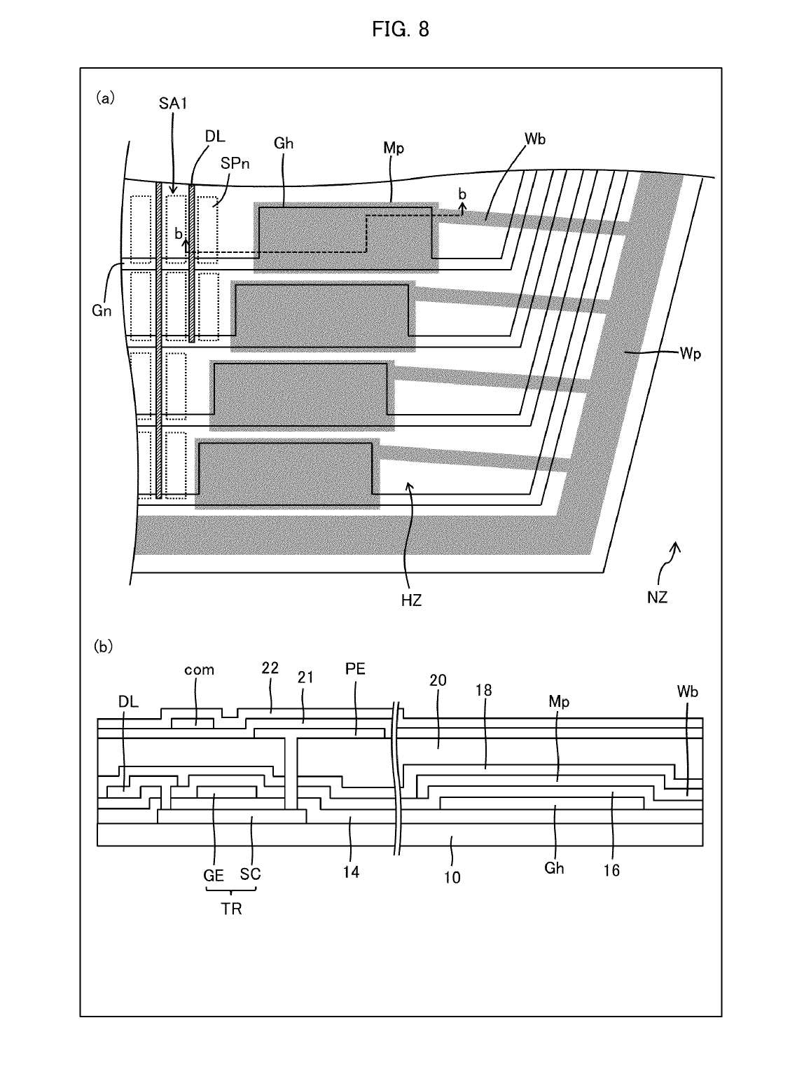

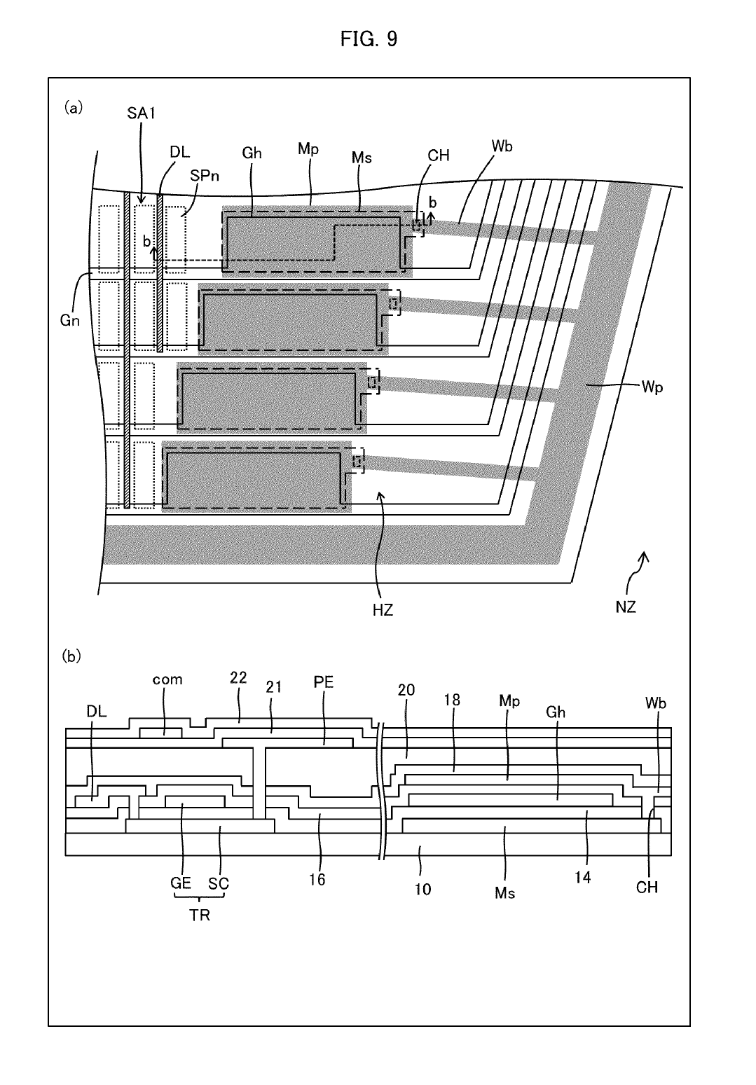

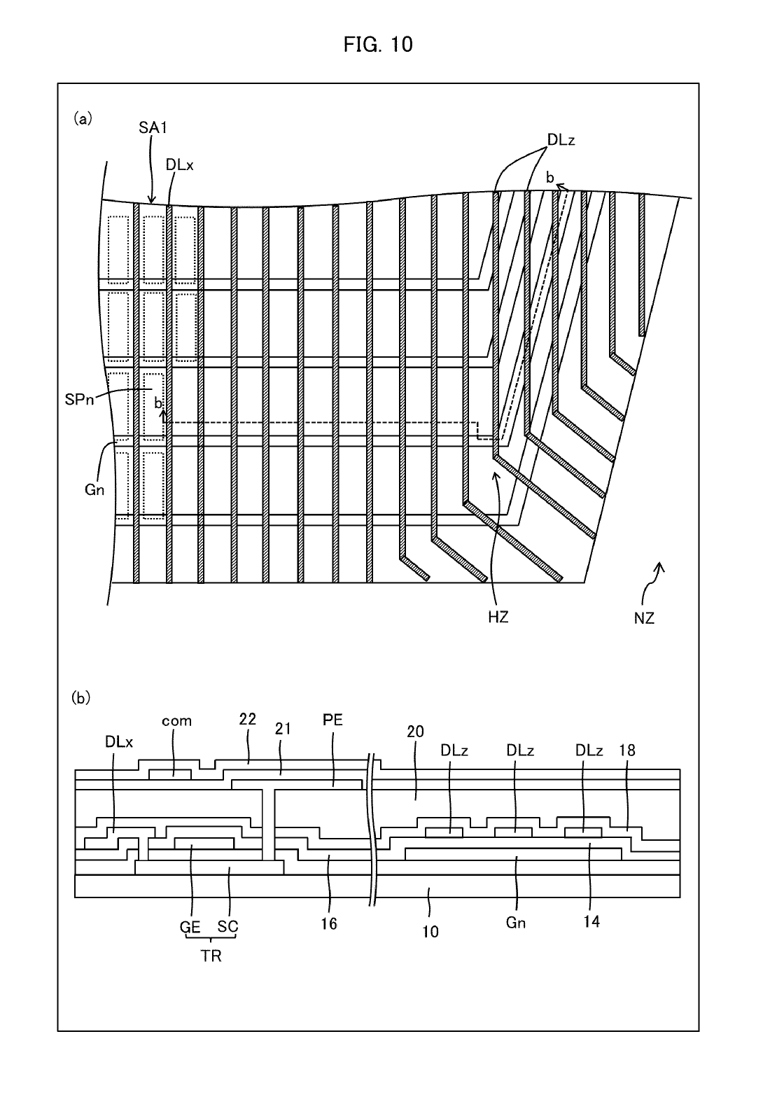

FIG. 7 is a schematic view illustrating variations of the liquid crystal panel of Embodiment 1. According to FIG. 1, the cutout NZ is provided in the liquid crystal panel LP. However, the liquid crystal panel is not limited to such a configuration. As illustrated in (a) of FIG. 7, a hole KZ can be provided in the liquid crystal panel LP. In this case, a non-display zone HZ is provided between the hole KZ and the display area DA. In the non-display zone HZ, a capacitance is added to the scanning signal line Gn which is provided so as to pass through the side areas SA1 and SA2. According to FIG. 1, the scanning signal line Gn, which is provided so as to pass through both sides (side areas SA1 and SA2) of the cutout NZ, is connected to both of the gate driver GD1 and the gate driver GD2. However, the liquid crystal panel is not limited to such a configuration. Alternatively, as illustrated in (b) of FIG. 7, the liquid crystal panel can be configured as follows. That is, the scanning signal line Gn and a scanning signal line GN are provided so as to face each other across the cutout NZ, as viewed from above. The scanning signal line Gn, which is provided so as to pass through the side area SA1, is connected to the gate driver GD1, and the scanning signal line GN, which is provided so as to pass through the side area SA2, is connected to the gate driver GD2. In this case, in the non-display zones HZ, a capacitance is added to each of the scanning signal lines Gn and GN (each of which is a low-load scanning signal line as compared with the scanning signal line Gm).

### Embodiment 2

(a) of FIG. 8 is a plan view illustrating a configuration of a vicinity of a cutout in Embodiment 2. (b) of FIG. 8 is a cross-sectional view illustrating the configuration of the vicinity of the cutout, viewed along arrows b-b in (a) of FIG. 8. According to Embodiment 1 (FIG. 2), electric conductors Ms are provided in a layer in which semiconductor films SC are provided, and capacitances are formed between (i) a scanning signal line Gn and (ii) corresponding ones of the electric conductors Ms. However, a liquid crystal panel is not limited to such a configuration. Alternatively, as illustrated in FIG. 8, a liquid crystal panel can be configured such that (a) electric conductors Mp are provided in a layer in which data signal lines DL and branch wires Wb are provided (formed by an identical process) and (b) capacitances are formed between (i) a scanning signal line Gn and (ii) corresponding ones of the electric conductors Mp. Specifically, the electric conductors Mp are provided in non-display zones HZ, and each of wide parts Gh of the scanning signal line Gn is provided so as to overlap with a corresponding one of the electric conductors Mp via an inorganic insulating film 16. Each of the electric conductors Mp is connected to a trunk wire Wp via a corresponding one of the branch wires Wb, which are provided in the layer in which the electric conductors Mp are provided. This allows a capacitance to be formed between (i) the each of the wide parts Gh of the scanning signal line Gn and (ii) the corresponding one of the electric conductors Mp. As such, it is possible to add the capacitance to the scanning signal line Gn, which is a low-load scanning signal line.

### Embodiment 3

(a) of FIG. 9 is a plan view illustrating a configuration of a vicinity of a cutout in Embodiment 3. (b) of FIG. 9 is a cross-sectional view illustrating the configuration of the vicinity of the cutout, viewed along arrows b-b in (a) of FIG. 9. According to Embodiment 3, electric conductors Ms, which are provided in a layer in which semiconductor films SC are provided, and electric conductors Mp, which are provided in a layer in which data signal lines DL are provided, are provided. Each of wide parts Gh of a scanning signal line Gn is provided so as to overlap with a corresponding one of the electric conductors Ms via an inorganic insulating film 14, and the each of the wide parts Gh of the scanning signal line Gn is provided so as to overlap with a corresponding one of the electric conductors Mp via an inorganic insulating film 16. This allows a capacitance to be formed between (a) the each of the wide parts Gh of the scanning signal line Gn and (b) the corresponding one of the electric conductors Ms, and allows a capacitance to be formed between (i) the each of the wide parts Gh of the scanning signal line Gn and (ii) the corresponding one of the electric conductors Mp. As such, it is possible to add the capacitances to the scanning signal line Gn, which is a low-load scanning signal line. According to Embodiment 3, it is possible to reduce a size of a region in which a capacitance is formed or to add a great capacitance, as compared with Embodiments 1 and 2.

### Embodiment 4

(a) of FIG. 10 is a plan view illustrating a configuration of a vicinity of a cutout in Embodiment 4. (b) of FIG. 10 is a cross-sectional view illustrating the configuration of the vicinity of the cutout, viewed along arrows b-b in (a) of FIG. 10. According to Embodiment 4, data signal lines DLz, ones of which extend into one of non-display zones HZ and the other ones of which extend into the other one of the non-display zones HZ, are provided, and capacitances are formed between (i) the data signal lines DLz and (ii) a scanning signal line Gn. In the non-display zones HZ, the scanning signal line Gn is provided so as to overlap with the data signal lines DLz via an inorganic insulating film 16. Therefore, it is possible to add capacitances to the scanning signal line Gn, which is a low-load scanning signal line.

The data signal lines DLz, which are provided so as to pass through the non-display zones HZ, are low-load data signal lines as compared with data signal lines DLx, which are provided so as not to pass through the non-display zones HZ (the number of sub pixels which are connected to each of the data signal lines DLz is less than the number of sub pixels which are connected to each of the data signal lines DLx). Therefore, by also adding a capacitance to each of the data signal lines DLz, it is possible to suppress vertical-striped luminance unevenness which can occur between a region located on an upper side or a lower side of a cutout NZ (a direction in which data signal lines extend is referred to as an up-and-down direction) and regions located on a right side and a left side of the cutout NZ (a direction in which scanning signal lines extend is referred to as a right-and-left direction). This is because, in a case where a data signal line DLx differs, in load, from a data signal line DLz, a source waveform (waveform of an electric potential of a data signal line) with an identical grayscale and an identical polarity differs between the data signal line DLx and the data signal line DLz, and an electric potential of a pixel electrode in a sub pixel connected to the data signal line DLx differs from an electric potential of a pixel electrode in a sub pixel connected to the data signal line DLz at a timing at which a scanning pulse returns (falls).

[Recap]

A display device in accordance with an embodiment of the present invention is suitable for not only a liquid crystal display but also an OLED (Organic Light Emitting Diode) display, a QLED (Quantum dot Light Emitting Diode) display, and the like.

The present invention is not limited to the embodiments, but can be altered by a skilled person in the art within the scope of the claims. The present invention also encompasses, in its technical scope, any embodiment derived by combining technical means disclosed in differing embodiments. Further, it is possible to form a new technical feature by combining the technical means disclosed in the respective embodiments.

[Aspect 1]

A display panel in which a cutout or a hole is provided, including:

a display area in which sub pixels are provided;

a non-display zone which is located between the cutout or the hole and the display area;

a scanning signal line which is provided so as to pass through the display area and the non-display zone;

an electric conductor which is at least partially located in the non-display zone; and

an insulating film, the scanning signal line being provided so as to overlap with the electric conductor via the insulating film.

[Aspect 2] The display panel as described in, for example, Aspect 1, wherein:

the scanning signal line has a wide part which is a part obtained by making the scanning signal line partially wider;

and the wide part is provided so as to overlap with the electric conductor via the insulating film.

[Aspect 3]

The display panel as described in, for example, Aspect 1 or 2, wherein:

the scanning signal line is connected to a transistor including a semiconductor film; and

the semiconductor film is provided in a layer in which the electric conductor is provided.

[Aspect 4]

The display panel as described in, for example, any one of Aspects 1 through 3, wherein a constant voltage is supplied to the electric conductor.

[Aspect 5]

The display panel as described in, for example, any one of Aspects 1 through 3, further including data signal lines through which data signals are supplied to the sub pixels, the electric conductor being part of one of the data signal lines.

[Aspect 6] The display panel as described in, for example, any one of Aspects 1 through 5, further including:

another electric conductor which is provided on an opposite side of the scanning signal line from the electric conductor; and

another insulating film,

the scanning signal line being provided so as to overlap with the another electric conductor via the another insulating film.

### REFERENCE SIGNS LIST

2 Display device
LP Liquid crystal panel
SPm, SPn Sub pixel
Gm, Gn Scanning signal line
Gh Wide part
TR Transistor (of a sub pixel)
DA Display area
NA Non-display area
SA1, SA2 Side area
NZ Cutout
KZ Hole
HZ Non-display zone
Ms, Mp Electric conductor
DL Data signal line
Wp Main wire
Wb Branch wire

1. A display panel in which a cutout or a hole is provided, comprising:
a display area in which sub pixels are provided;
a non-display zone which is located between the cutout or the hole and the display area;
a scanning signal line which is provided so as to pass through the display area and the non-display zone;
an electric conductor which is at least partially located in the non-display zone; and
an insulating film,
the scanning signal line being provided so as to overlap with the electric conductor via the insulating film.

2. The display panel as set forth in claim 1, wherein:
the scanning signal line has a wide part which is a part obtained by making the scanning signal line partially wider; and
the wide part is provided so as to overlap with the electric conductor via the insulating film.

3. The display panel as set forth in claim 1, wherein:
the scanning signal line is connected to a transistor including a semiconductor film; and
the semiconductor film is provided in a layer in which the electric conductor is provided.

4. The display panel as set forth in claim 1, wherein a constant voltage is supplied to the electric conductor.

5. The display panel as set forth in claim 1, further comprising data signal lines through which data signals are supplied to the sub pixels, the electric conductor being part of one of the data signal lines.

6. The display panel as set forth in claim 1, further comprising:
another electric conductor which is provided on an opposite side of the scanning signal line from the electric conductor; and
another insulating film,
the scanning signal line being provided so as to overlap with the another electric conductor via the another insulating film.
